(19) United States
(12) Patent Application Publication
(10) Pub. No.: US 2025/0166975 A1
(43) Pub. Date: May 22, 2025

(54) SUBSTRATE PROCESSING APPARATUS AND SUBSTRATE PROCESSING METHOD

(71) Applicant: Tokyo Electron Limited, Tokyo (JP)

(72) Inventors: Lifu LI, Miyagi (JP); Junya KURAMOTO, Miyagi (JP); Takashi ARAMAKI, Miyagi (JP); Hiroshi TSUJIMOTO, Miyagi (JP)

(21) Appl. No.: 19/032,746

(22) Filed: Jan. 21, 2025

Related U.S. Application Data
(62) Division of application No. 17/453,027, filed on Nov. 1, 2021.

(30) Foreign Application Priority Data
Nov. 13, 2020 (JP) 2020-189593

(51) Int. Cl. H01J 37/32

(52) U.S. Cl. CPC H01J 37/32449; H01J 37/32009; H01J 37/32532; H01J 37/32715; H01J 2237/2007; H01J 2237/327

(57) ABSTRACT

A substrate processing apparatus includes a processing chamber having a substrate support configured to support a substrate, a gas supply configured to supply a plurality of processing gases to the processing chamber, a plasma generator configured to generate plasma of the processing gases, and a controller configured to control the gas supply. The gas supply includes a first gas supply configured to supply a first processing gas to the processing chamber, and a second gas supply configured to inject a second processing gas to the first processing gas supplied to the processing chamber.

### CROSS-REFERENCE TO RELATED APPLICATIONS

This application is a divisional application of U.S. patent application Ser. No. 17/453,027, filed on Nov. 1, 2021, which is based upon and claims priority to Japanese Patent Application No. 2020-189593, filed on Nov. 13, 2020, the entire contents of which are incorporated herein by reference.

### BACKGROUND

### 1. Field of the Invention

The present disclosure relates to substrate processing apparatuses and substrate processing methods.

### 2. Description of the Related Art

An example of a known substrate processing apparatus supplies a processing gas from a gas source to a chamber, and performs a desired processing on a substrate using plasma of the processing gas.

As an example, Japanese Laid-Open Patent Publication No. 2008-244294 proposes a processing gas supply apparatus including a gas source which supplies a processing gas, a vacuum processing chamber including a plasma generator which generates plasma by supplying high frequency energy to the processing gas supplied to the vacuum processing chamber, and a gas supply line which supplies the processing gas supplied from the gas source to the vacuum processing chamber via a gas flow controller, a gas supply pipe, and a gas circuit breaker. The processing gas supply apparatus also includes a plasma emission detector which detects plasma emission inside the vacuum processing chamber to detect an amount of the processing gas component supplied via the gas supply line, based on the detected plasma emission, and a controller. The controller measures an arrival time and a reduction time of the gas supply line, based on an elapsed time from a time when the gas circuit breaker releases or interrupts the processing gas until the amount of the processing gas component reaches a predetermined amount. The controller controls the release or interrupt timing of the gas circuit breaker, based on the arrival time and the reduction time.

### SUMMARY

According to one aspect of the embodiments, a substrate processing apparatus includes a processing chamber having a substrate support configured to support a substrate; a gas supply configured to supply a plurality of processing gases to the processing chamber; a plasma generator configured to generate plasma of the processing gases; and a controller configured to control the gas supply, wherein the gas supply includes a first gas supply configured to supply a first processing gas to the processing chamber, and a second gas supply configured to inject a second processing gas to the first processing gas supplied to the processing chamber.

The object and advantages of the embodiments will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWINGS

FIG. 1 is a diagram illustrating an example of a configuration of a plasma processing system according to one embodiment.

FIG. 2 is a diagram illustrating an example of a configuration of a gas supply.

FIG. 3A, FIG. 3B, and FIG. 3C are timing charts illustrating examples of gas supply timings.

FIG. 4 is a graph illustrating an example of plasma emission.

FIG. 5A and FIG. 5B are diagrams schematically illustrating an example of behaviors of dissociated gases.

FIG. 6A and FIG. 6B are graphs illustrating examples of selective etching ratio of a mask with respect to a film during a substrate processing.

FIG. 7A, FIG. 7B, and FIG. 7C are graphs for explaining an example of a relationship between a delay time and a concave shape.

### DETAILED DESCRIPTION

There are demands to improve controllability when processing substrates.

Accordingly, it is desirable to provide a substrate processing apparatus and a substrate processing method which can improve the controllability of the substrate processing.

A description will hereinafter be given of embodiments of the present invention with reference to the drawings. In the figures, those constituent elements that are the same are designated by the same reference numerals, and a repeated description of the same constituent elements may be omitted.

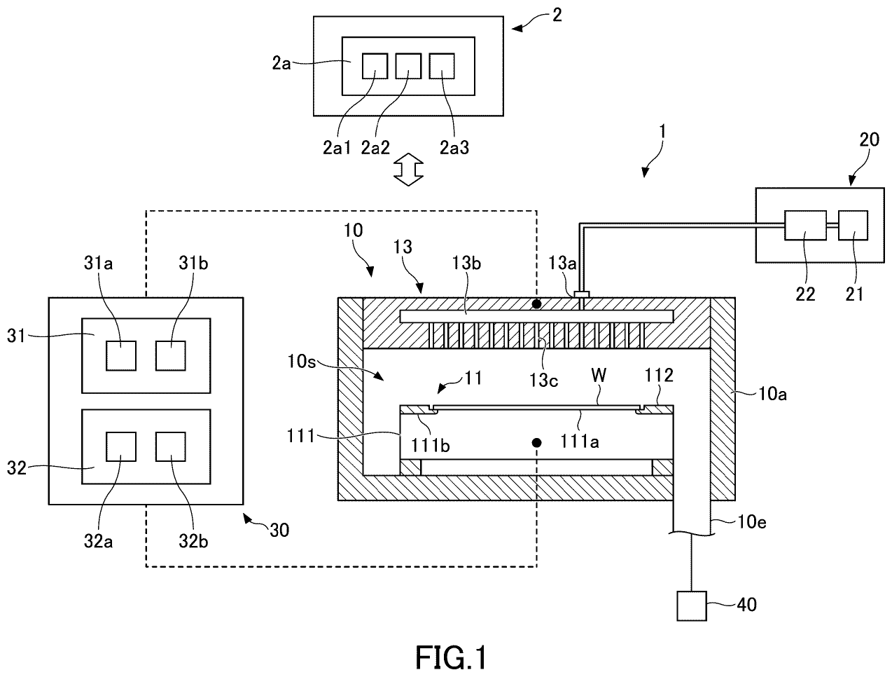

An example of a configuration of a plasma processing system will be described. FIG. 1 is a diagram illustrating the example of the configuration of the plasma processing system according to one embodiment.

The plasma processing system includes a capacitively coupled plasma processing apparatus 1, and a controller 2. The capacitively coupled plasma processing apparatus 1 includes a plasma processing chamber 10, a gas supply 20, a power supply 30, and an exhaust system 40. The plasma processing apparatus 1 also includes a substrate support 11, and a gas introducing part. The gas introducing part is configured to introduce at least one processing gas into the plasma processing chamber 10. The gas introducing part includes a shower head 13. The substrate support 11 is disposed inside the plasma processing chamber 10. The shower head 13 is disposed above the substrate support 11. In one embodiment, the shower head 13 forms at least a portion of a ceiling of the plasma processing chamber 10. The plasma processing chamber 10 has the shower head 13, and a plasma processing space 10s defined by the substrate support 11 and a sidewall 10a of the plasma processing chamber 10. The plasma processing chamber 10 has at least one gas supply port for supplying at least one processing gas to the plasma processing space 10s, and at least one gas discharge port 10e for discharging the gas from the plasma processing space 10s. The sidewall 10a is grounded. The shower head 13 and the substrate support 11 are electrically isolated from an enclosure of the plasma processing chamber 10.

The substrate support 11 includes a body 111, and a ring assembly 112. The body 111 has a central region (or substrate support surface) 111a for supporting a substrate (or wafer) W, and an annular region (or ring support surface) 111b for supporting the ring assembly 112. The annular region 111b of the body 111 surrounds the central region 111a of the body 111 in a plan view. The substrate W is disposed on the central region 111a of the body 111, and the ring assembly 112 is disposed on the annular region 111b of the body 111, so as to surround the substrate W on the central region 111a of the body 111. In one embodiment, the body 111 includes a base, and an electrostatic chuck. The base includes an electrically conductive member. The electrically conductive member of the base functions as a lower electrode. The electrostatic chuck is disposed on the base. An upper surface of the electrostatic chuck has a substrate support surface 111a. The ring assembly 112 includes one or a plurality of annular members. At least one annular member of the one or plurality of annular members may be an edge ring. In addition, although not illustrated in FIG. 1, the substrate support 11 may include a temperature control module configured to control or adjust at least one of the electrostatic chuck, the ring assembly 112, and the substrate W to a target temperature. The temperature control module may include a heater, a heat transfer medium, a flow passage, or a combination thereof. A heat transfer fluid, such as brine and gas, flows through the flow passage. Moreover, the substrate support 11 may include a heat transfer gas supply configured to supply a heat transfer gas between a back surface of the substrate W and the substrate support surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introducing ports 13c. The processing gas supplied to the gas supply port 13a, passes through the gas diffusion chamber 13b, and is introduced into the plasma processing space 10s from the plurality of gas introducing ports 13c. Further, the shower head 13 includes an electrically conductive member. The electrically conductive member of the shower head 13 functions as an upper electrode. The gas introducing part may include, in addition to the shower head 13, one or a plurality of side gas injectors (SGI) mounted at one or a plurality of openings formed in the sidewall 10a, respectively.

The gas supply 20 may include at least one gas source 21, and at least one flow controller 22. In one embodiment, the gas supply 20 is configured to supply at least one processing gas from a corresponding gas source 21 among the plurality of gas sources 21 to the shower head 13, via a corresponding flow controller 22 among the plurality of flow controllers 22, respectively. Each flow controller 22 may include a mass flow controller or a pressure controlled flow controller, for example. In addition, the gas supply 20 may include one or a plurality of flow modulation devices (or flow-rate modulation devices) which modulate or pulse a flow rate of the at least one processing gas.

The power supply 30 includes a radio frequency (RF) power supply 31 which is coupled to the plasma processing chamber 10 via at least one impedance matching circuit. The RF power supply 31 is configured to supply at least one RF signal (or RF power), such as a source RF signal and a bias RF signal, to the electrically conductive member of the substrate support 11 and/or a conductive member of the shower head 13. Hence, plasma is generated from the at least one processing gas supplied to the plasma processing space 10s. Accordingly, the RF power supply 31 may function as at least a part of a plasma generator configured to generate the plasma from one or a plurality of processing gases in the plasma processing chamber 10. Moreover, by supplying the bias RF signal to the electrically conductive member of the substrate support 11, a bias potential is generated in the substrate W, thereby enabling an ion component in the generated plasma to be drawn toward the substrate W.

In one embodiment, the RF power supply 31 includes a first RF generator 31a, and a second RF generator 31b. The first RF generator 31a is coupled to the electrically conductive member of the substrate support 11 and/or the electrically conductive member of the shower head 13, via at least one impedance matching circuit, and is configured to generate a source RF signal (or source RF power) for use in generating the plasma. In one embodiment, the source RF signal has a frequency in a range of 13 MHz to 150 MHz. In one embodiment, the first RF generator 31a may be configured to generate a plurality of source RF signals having different frequencies. The generated one or plurality of source RF signals are supplied to the electrically conductive member of the substrate support 11 and/or the electrically conductive member of the shower head 13. The second RF generator 31b is coupled to the electrically conductive member of the substrate support 11, via at least one impedance matching circuit, and is configured to generate a bias RF signal (or bias RF power). In one embodiment, the bias RF signal has a frequency lower than the frequency of the source RF signal. In one embodiment, the bias RF signal has a frequency in a range of 400 kHz to 13.56 MHZ. In one embodiment, the second RF generator 31b may be configured to generate a plurality of bias RF signals having different frequencies. The generated one or plurality of bias RF signals are supplied to the electrically conductive member of the substrate support 11. Further, in various embodiments, at least one of the source RF signal and the bias RF signal may be pulsed.

The power supply 30 may include a DC power supply 32 which is coupled to the plasma processing chamber 10. The DC power supply 32 includes a first DC generator 32a, and a second DC generator 32b. In one embodiment, the first DC generator 32a is connected to the electrically conductive member of the substrate support 11, and is configured to generate a first DC signal. The generated first bias DC signal is supplied to the electrically conductive member of the substrate support 11. In one embodiment, the first DC signal may be supplied to other electrodes, such as electrodes in the electrostatic chuck. In one embodiment, the second DC generator 32b is connected to the electrically conductive member of the shower head 13, and is configured to generate a second DC signal. The generated second DC signal is supplied to the electrically conductive member of the shower head 13. In various embodiments, at least one of the first DC signal and the second DC signal may be pulsed. The first and second DC generators 32a and 32b may be provided in addition to the RF power supply 31, and the first DC generator 32a may be provided in place of the second RF generator 31b.

The exhaust system 40 may be connected to the gas discharge port 10e provided at a bottom of the plasma processing chamber 10, for example. The exhaust system 40 may include a pressure regulating valve, and a vacuum pump. The pressure regulating valve can regulate the pressure inside the plasma processing space 10s. The vacuum pump may include a turbo-molecular pump, a dry pump, or a combination thereof.

The controller 2 processes computer-executable instructions or commands which cause the plasma processing apparatus 1 to execute various processes or steps described in the present disclosure. The controller 2 may be configured to control each element of the plasma processing apparatus 1 to perform the various processes or steps described below. In one embodiment, a part or all of the controller 2 may be included in the plasma processing apparatus 1. The controller 2 may include a computer 2a, for example. The computer 2a may include a processor 2a1, such as a central processing unit (CPU), a storage device 2a2, and a communication interface 2a3. The processor 2a1 may be configured to perform various control operations, based on one or more programs stored in the storage device 2a2. The storage device 2a2 may include a random access memory (RAM), a read only memory (ROM), a hard disk drive (HDD), a solid state drive (SSD), or a combination thereof. The communication interface 2a3 may communicate with the plasma processing apparatus 1, via a communication line, such as a local area network (LAN) or the like.

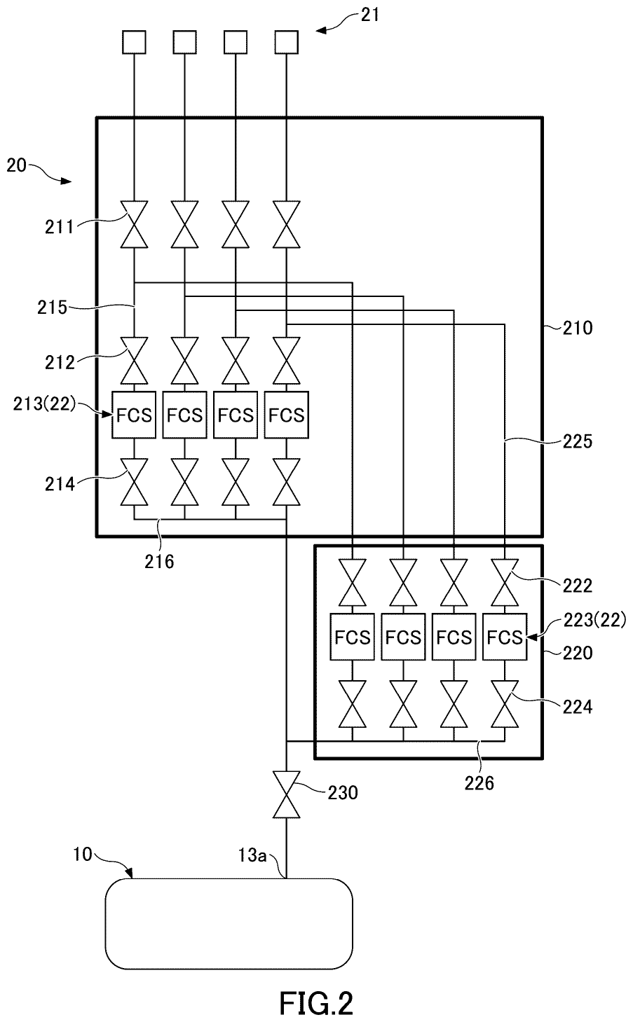

Next, the gas supply 20 will be described in more detail, with reference to FIG. 2. FIG. 2 is a diagram illustrating an example of a configuration of the gas supply 20.

The gas supply 20 includes a plurality of gas sources 21, a gas box 210, an injection box 220, and a valve 230. The gas box 210 is an example of a first gas supply configured to supply a first processing gas to the plasma processing chamber 10, and the injection box 220 is an example of a second gas supply configured to inject a second processing gas to the first processing gas supplied to the plasma processing chamber 10.

In the example of the gas supply 20 illustrated in FIG. 2, four gas sources 21 are provided. In the following description, the example of the gas supply 20 described supplies a C₄F₆ gas, a C₄F₈ gas, a NF₃ gas, and an O₂ gas, as the processing gases (or a gas mixture).

The gas box 210 includes valves 211, valves 212, flow controllers 213 (22), valves 214, and gas passages 215 and 216. The gas passage 215 is provided for each of gas species supplied from the gas sources 21. In the example illustrated in FIG. 2, the gas passage 215 is provided in four systems. An upstream side of each gas passage 215 is connected to a corresponding one of the gas sources 21, respectively. The valve 211, the valve 212, the flow controller 213 (22), and the valve 214 are provided in the corresponding gas flow passage 215 in this order from the corresponding gas source 21. Downstream sides of the gas passages 215 merge, and connect to the gas passage 216.

In addition, a downstream side of the gas passage 216 connects to the gas supply port 13a of the plasma processing chamber 10. Further, the valve 230 is provided in the gas passage 216.

The injection box 220 includes valves 222, flow controllers 223 (22), valves 224, and gas passages 225 and 226. The gas passage 225 is provided for each of the gas sources 21. In the example illustrated in FIG. 2, the gas passage 225 is provided in four systems. An upstream side of each gas passage 225 is connected to a corresponding one of the gas passages 215 between valves 211 and valves 212, respectively. The valve 222, the flow controller 223 (22), and the valve 224 are provided in the corresponding gas flow passage 225 in this order from the corresponding gas source 21. Downstream sides of the gas passages 225 merge, and connect to the gas passage 226. The downstream side of the gas passage 226 connects to the gas passage 216 at a position on the upstream side of the valve 230.

The controller 2 illustrated in FIG. 1 controls the valves 211, 212, 214, 222, 224, and 230, and the flow controllers 213 and 223.

When supplying the processing gases from the gas supply 20 to the plasma processing chamber 10, the controller 2 opens the valve 230.

In addition, when the processing gases are

supplied from the gas sources 21 to the plasma processing chamber 10 via the gas box 210, the controller 2 opens the valves 211 and 212, and closes the valves 222 and 224. The controller 2 controls the flow controllers 213, to control the flow rates of the processing gases. Further, the controller 2 opens and closes the valves 214, to control the supply of the processing gases.

When the processing gases are supplied from the gas sources 21 to the plasma processing chamber 10 via the injection box 220, the controller 2 opens the valves 211 and 222, and closes the valves 212 and 214. The controller 2 controls the flow controllers 223, to control the flow rates of the processing gases. In addition, the controller 2 opens and closes the valves 224, to control the supply of the processing gases.

Accordingly, the gas supply 20 is configured to be able to select whether to supply the processing gases from the gas sources 21 to the plasma processing chamber 10 via the gas box 210, or to supply the processing gases from the gas sources 21 to the plasma processing chamber 10 via the injection box 220.

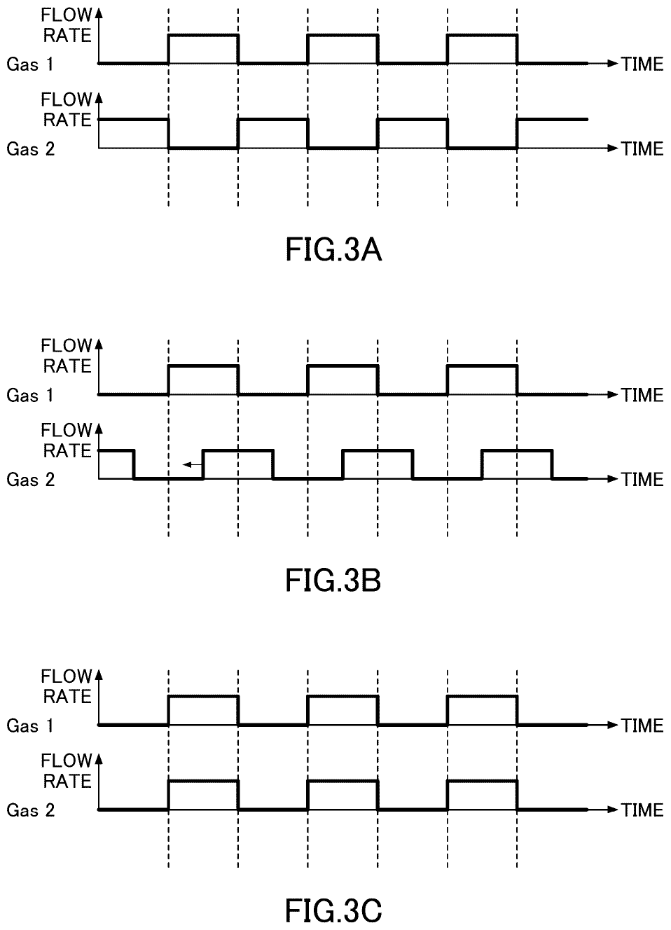

Next, an example of the control of the gas supply by the controller 2 will be described, with reference to FIG. 3A through FIG. 3C. FIG. 3A through FIG. 3C are timing charts illustrating examples of gas supply timings. In FIG. 3A through FIG. 3C, Gas 1 denotes the processing gases supplied to the plasma processing chamber 10 via the gas box 210, and Gas 2 denotes the processing gases supplied to the plasma processing chamber 10 via the injection box 220. In FIG. 3A through FIG. 3C, the ordinate indicates the flow rate, and the abscissa indicates the time.

In FIG. 3A, the controller 2 controls the opening and closing of the valves 214 to simultaneously supply the processing gases Gas 1 intermittently (or periodically) to the plasma processing chamber 10 from the gas box 210. The controller 2 also controls the opening and closing of the valves 244 to simultaneously supply the processing gases Gas 2 intermittently (or periodically) to the plasma processing chamber 10 from the injection box 220. The controller 2 controls the opening and closing of the valves 214 and 224, so that the processing gases Gas 1 and the processing gases Gas 2 are alternately supplied.

In FIG. 3B, the controller 2 controls the opening and closing of the valves 214 to simultaneously supply the processing gases Gas 1 intermittently (or periodically) to the plasma processing chamber 10 from the gas box 210. The controller 2 also controls the opening and closing of the valves 244 to simultaneously supply the processing gases Gas 2 intermittently (or periodically) to the plasma processing chamber 10 from the injection box 220. The controller 2 controls the opening and closing of valves 214 and 224, so that the processing gases Gas 1 and the processing gases Gas 2 are supplied at different timings. For example, the controller 2 offsets the opening and closing timings of the valves 224, so that the processing gases Gas 1 and the processing gases Gas 2 are supplied to the plasma processing chamber 10 at different timings.

The opening and closing timings of the valves 224 are preferably offset by a time greater than or equal to 0.5 second.

In FIG. 3C, the controller 2 controls the opening and closing of the valves 214 to simultaneously supply the processing gases Gas 1 intermittently (or periodically) to the plasma processing chamber 10 from the gas box 210. The controller 2 also controls the opening and closing of the valves 244 to simultaneously supply the processing gases Gas 2 intermittently (or periodically) to the plasma processing chamber 10 from the injection box 220. The controller 2 controls the opening and closing of the valves 214 and 224, so that the processing gases Gas 1 and the processing gases Gas 2 are supplied at the same timing.

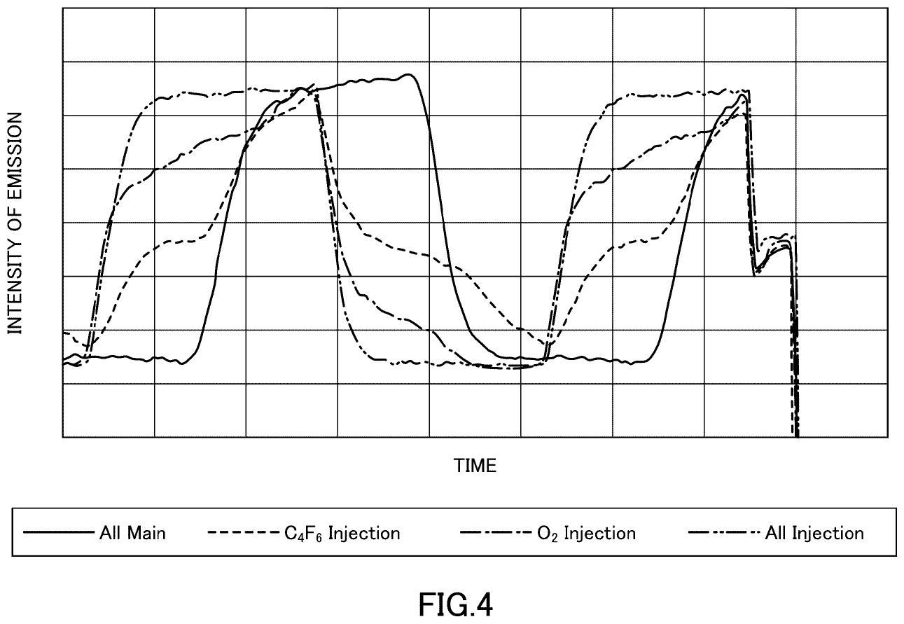

FIG. 4 is a graph illustrating an example of plasma emission. In FIG. 4, the ordinate indicates the intensity of emission (777 nm) due to O plasma detected by an optical emission spectrometer (OES), and the abscissa indicates the time.

In FIG. 4, a solid line “All Main” indicates a case where all of the processing gases, namely, the C₄F₆ gas, the C₄F₈ gas, the NF₃ gas, and the O₂ gas, are supplied from the gas box 210. In this case, the intensity of emission varies with a generally rectangular shape including a sharp rise.

In FIG. 4, a two-dot chain line “All Injection” indicates a case where all of the processing gases, namely, the C₄F₆ gas, the C₄F₈ gas, the NF₃ gas, and the O₂ gas, are supplied from the injection box 220. In this case, the intensity of emission varies with a generally rectangular shape including a sharp rise. The rise timings of the waveforms indicated by the solid line “All Main” and the two-dot chain line “All Injection” differ, according to delay times of the gas box 210 and the injection box 220.

In FIG. 4, a dashed line “C₄F₆ Injection” indicates a case where the C₄F₆ gas is supplied from the injection box 220, and the other processing gases, namely, the C₄F₈ gas, the NF₃ gas, and the O₂ gas, are supplied from the gas box 210. In this case, the intensity of emission varies in multiple steps. In other words, the energy of the plasma varies in multiple steps.

In FIG. 4, a one-dot chain line “O₂ Injection” indicates a case where the O₂ gas is supplied from the injection box 220, and the other processing gases, namely, the C₄F₆ gas, the C₄F₈ gas, and the NF₃ gas, are supplied from the gas box 210. In this case, the intensity of emission varies with a shape including a gradual rise. In other words, the energy of the plasma varies gradually.

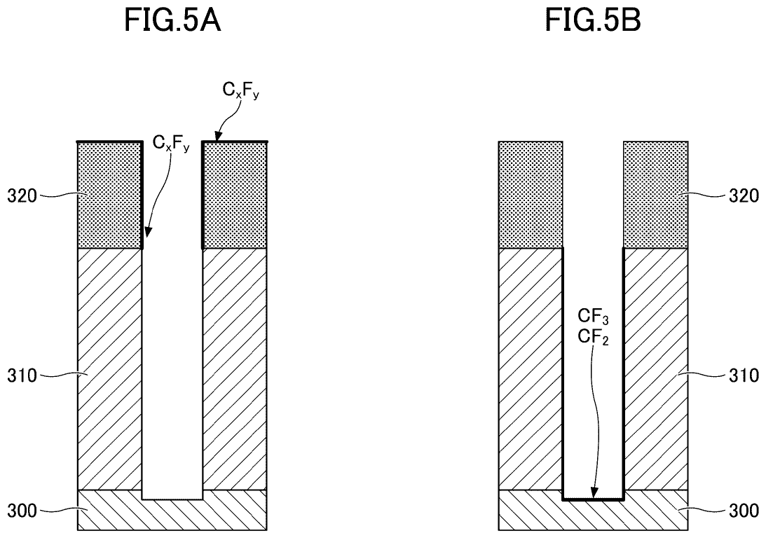

FIG. 5A and FIG. 5B are diagrams schematically illustrating an example of behaviors of dissociated gases. In this example, it is assumed that a base 300, a film 310, and a mask 320 are laminated on the substrate W. In addition, it is assumed that a concave shape, such as a blanket, a hole pattern, or the like, is formed in the substrate W.

The dissociated states of CF-based gases, such as the C₄F₆ gas and the C₄F₈ gas, which are examples of the processing gases, vary according to the energy of the plasma.

FIG. 5A is a schematic diagram illustrating the gas behavior at a low energy. In a case where the energy of the plasma is low, that is, the intensity of emission illustrated in FIG. 4 is low, the C₄F₆ and C₄F₈ gases dissociate to CₓF_{y}, for example. As indicated by a bold line in FIG. 5A, CₓF_{y} is deposited on an upper surface of the mask 320, and an upper portion of the concave shape, that is, side surfaces of the mask 320.

FIG. 5B is a schematic diagram illustrating the gas behavior at a high energy. In a case where the energy of the plasma is high, that is, the intensity of emission illustrated in FIG. 4 is high, the C₄F₆ and C₄F₈ gases dissociate to CF₂ or CF₃, for example. As indicated by a bold line in FIG. 5B, CF₂ or CF₃ having a low molecular weight compared to CₓF_{y} is deposited on a lower portion of the concave shape, that is, side surfaces of the film 310 and an upper surface of the base 300.

Accordingly, the plasma state can be adjusted, by varying the supply timing of at least one of the plurality of processing gases supplied from the gas sources 21. For example, as indicated by the dashed line in FIG. 4, the energy of the plasma can be varied in multiple steps, and as indicated by the one-dot chain line in FIG. 4, the energy of the plasma can be varied gradually. Hence, it is possible to adjust the dissociated states of the gases. Further, as illustrated in FIG. 5A and FIG. 5B, it is possible to adjust the arrival or destination positions of the dissociated gases with respect to the concave shape.

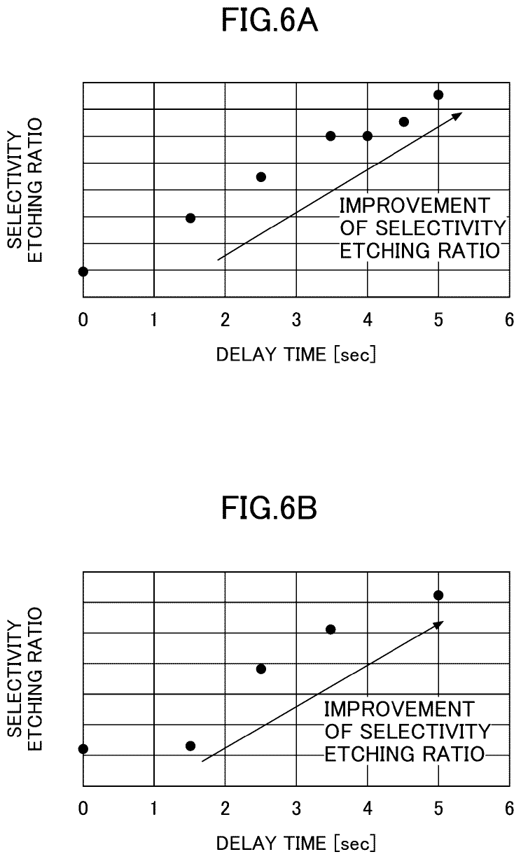

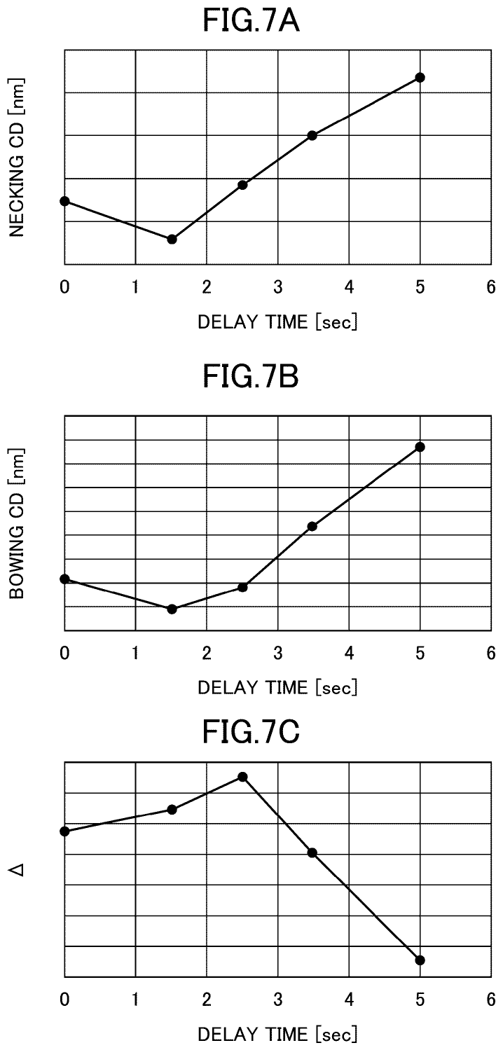

Next, an example of the results of the substrate processing method according to this embodiment will be described, with reference to FIG. 6A, FIG. 6B, and FIG. 7A through FIG. 7C.

FIG. 6A and FIG. 6B are graphs illustrating examples of selective etching ratio of the mask 320 with respect to the film 310 during the substrate processing. FIG. 6A illustrates a case where an etching process is performed on the substrate W which is not formed with a concavo-convex pattern. FIG. 6B illustrates a case where the etching process is performed on the substrate W which is formed with the concave shape of the hole. In FIG. 6A and FIG. 6B, the abscissa indicates the delay time (or offset time) between the gases supplied from the gas box 210, and the gases supplied from the injection box 220, and the ordinate indicates the selective etching ratio of the film 310 with respect to the mask 320.

In this example, the C₄F₆ gas, the C₄F₈ gas, and the NF₃ gas from the gas box 210 are supplied intermittently, so that the three gases are simultaneously supplied in steps of 5 seconds, and the simultaneous supply of the three gases is stopped in steps of 5seconds, and such steps are repeated. More particularly, the C₄F₆ gas, the C₄F₈ gas, and the NF₃ gas from the gas box 210 are simultaneously supplied in one step of 5 seconds, the simultaneous supply of the C₄F₆ gas, the C₄F₈ gas, and the NF₃ gas from the gas box 210 is stopped in the next one step of 5 seconds, and such steps are alternately repeated. In addition, the O₂ gas from the injection box 220 is supplied intermittently, so that this gas is supplied in steps of 5 seconds, and the supply of this gas is stopped in steps of 5 seconds, and such steps are repeated. That is, the O₂ gas from the injection box 220 is supplied in one step of 5 seconds, the supply of the O₂ gas from the injection box 220 is stopped in the next one step of 5 seconds, and such steps are alternately repeated. Moreover, the delay time in FIG. 3A is set to 0 second. The delay time is set so that the supply timings of the processing gases supplied from the injection box 220 occur earlier, as indicated by a direction of an arrow in FIG. 3B. Further, the delay time in FIG. 3C is set to 5 seconds.

As illustrated in FIG. 6A and FIG. 6B, it was confirmed that the selective etching ratio of the mask 320 with respect to the film 310 can be varied by varying the delay time. In the examples illustrated in FIG. 6A and FIG. 6B, it was confirmed that the selective etching ratio of the mask 320 with respect to the film 310 becomes higher as the delay time is increased.

FIG. 7A, FIG. 7B, and FIG. 7C are graphs for explaining an example of a relationship between the delay time and the concave shape. FIG. 7A is an example of the graph illustrating the relationship between a necking CD value of the concave shape and delay time. FIG. 7B is an example of the graph illustrating the relationship between a bowing CD value of the concave shape and the delay time. FIG. 7C is an example of the graph illustrating the relationship between the ratio Δ={(Necking CD value)/(Bowing CD value)} of the necking CD value to the bowing CD value, and the delay time.

As illustrated in FIG. 7A through FIG. 7C, it was confirmed that the concave shape of the film 310 can be adjusted, by changing the delay time. For example, in the examples illustrated in FIG. 7A through FIG. 7C, it was confirmed that the ratio A becomes a maximum value, that is, a verticality of the concave shape can be improved, by setting the delay time to 2.5 seconds.

According to each of the embodiments and modifications, it is possible to improve the controllability of the substrate processing.

While certain embodiments have been described for the plasma processing system, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

Although the gas supply 20 of the embodiments described above include the gas box 210 and the injection box 220, the gas supply 20 is not limited to such a configuration. The injection box 220 may be omitted, if the valve 214 for each processing gas has a configuration including an independently controllable delay time.

What is claimed is:

1. A substrate processing method to be implemented in a substrate processing apparatus which includes a processing chamber having a substrate support configured to support a substrate, a gas supply including a first gas supply configured to supply a first processing gas to the processing chamber, and a second gas supply configured to inject a second processing gas to the first processing gas supplied to the processing chamber, and a plasma generator configured to generate plasma of the processing gases, the substrate processing method comprising:
supplying the second processing gas from the second gas supply to the processing chamber at a timing different from a timing at which the first processing gas from the first gas supply is supplied to the processing chamber,
wherein the supplying supplies the second processing gas from the second gas supply to the processing chamber at an offset timing different from the timing at which the first processing gas from the first gas supply is supplied to the processing chamber, so that an intensity of emission of the plasma varies in multiple steps.

2. The substrate processing method as claimed in claim 1, wherein the supplying periodically supplies the first processing gas from the first gas supply and the second processing gas from the second gas supply to the processing chamber.

3. The substrate processing method as claimed in claim 1, wherein the offset timing amounts to a time of 0.5 second or more.

4. The substrate processing method as claimed in claim 1, wherein
the first processing gas includes a CF-based gas, and
the second processing gas includes a CF-based gas different from the first processing gas.

5. The substrate processing method as claimed in claim 4, wherein
the first processing gas includes a C₄F₈ gas, and
the second processing gas includes a C₄F₆ gas.

6. The substrate processing method as claimed in claim 4, wherein
the first processing gas includes a gas mixture of the C₄F₈ gas, a NF₃ gas, and an O₂ gas, and
the second processing gas includes a C₄F₆ gas.
